(19) United States
(12) Patent Application Publication
(10) Pub. No.: US 2009/0035098 A1
(43) Pub. Date: Feb. 5, 2009

(54) LID OPENING/CLOSING SYSTEM FOR CLOSED CONTAINER AND SUBSTRATE PROCESSING METHOD USING SAME

(75) Inventors: Hiroshi IGARASHI, Tokyo (JP); Toshihiko Miyajima, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TDK Corporation, Tokyo (JP)

(21) Appl. No.: 11/949,409

(22) Filed: Dec. 3, 2007

(30) Foreign Application Priority Data
Jul. 30, 2007 (JP) 2007-197321

(51) Int. Cl. H01L 21/677

(52) U.S. Cl. 414/217

(57) ABSTRACT

An object is to provide a FIMS system that can be loaded with a plurality of low profile pods that are arranged vertically one above another. A tunnel is provided between a position on a support mechanism on which a pod is to be set and a mini environment that is in communication with the FISM. The position of the pod at which a lid of the pod is detached from the pod after the lid is held by a FIMS door and a position of the pod to which the pod is brought after the detachment of the lid and at which a wafer can be brought into/out of the pod are designed to be inside the tunnel. In addition, the lid detached from the pod and the door can be located in a housing space provided in the tunnel.

### BACKGROUND OF THE INVENTION

1. Field of the Invention

The present invention relates to a kind of what is called a FIMS (Front-opening Interface Mechanical Standard) system that is used in a semiconductor manufacturing process or the like to transfer reticles, wafers or the like stored in the interior of a transfer container called a pod, for example, from one semiconductor processing apparatus to another. More specifically, the present invention relates to a FIMS system or a lid opening and closing system that simultaneously handles a plurality of pods called FOUP (Front-Opening Unified Pod) or low profile airtight containers that can store a few reticles or the like and opens/closes the lids of the pods to bring reticles or the like into/out of the pods. The present invention also relates to a substrate processing method using such a system.

2. Related Background Art

In the past, the semiconductor manufacturing process had been performed in what is called a clean room that is constructed by establishing a high degree of cleanliness in the room in which semiconductor wafers are handled. In recent years, however, in view of an increase in the wafer size and with a view to reduce cost incurred in maintenance of the clean room, use has been made of a method of keeping clean only the interior of a processing apparatus, a pod (or wafer container) and a small space through which substrates or wafers are transferred between the pod and the processing apparatus.

The pod is composed of a body portion of a substantially cubical shape having shelves provided therein that can hold a plurality of wafers in a parallel and separated state and an opening provided on one side thereof through which wafers can be brought into/out of it, and a lid for closing the opening. Those pods which have an opening portion provided not on the bottom but on one lateral side thereof (i.e. the front side to be opposed to the small space) are collectively called FOUP (Front-Opening Unified Pod). The present invention is directed mainly to technologies in which the FOUP is used. In the past, pods that can each house more than ten wafers had been used to increase the production efficiency. Recently, however, with an increase in the diameter of wafers or an increase in the number of steps of wafer processing, there has arisen the idea that it is preferable that only a few wafers be stored in one each pod and wafers be supplied to each apparatus in a small lot. Such a low profile pod that is specialized to house a few wafers and handling thereof is described in detail in Japanese Patent Application Laid-Open No. 2004-262654.

A system that constitutes the above mentioned small space has an opening portion opposed to the opening of the pod, a door that closes the opening portion, a processing apparatus side opening portion provided on the semiconductor processing apparatus side, and a transferring robot that is adapted to reach into the interior of the pod through the pod side opening portion to pick up a wafer and transfer the wafer into the processing apparatus through the processing apparatus side opening portion. The system that constitutes the small space also has a support table that supports the pod in such a way that the pod opening is placed just in front of the door. Typically, the support table is adapted to be movable toward and away from the door over a predetermined distance. When the wafers in a pod are to be transferred into the processing apparatus, the pod placed on the support table is moved until the lid of the pod abuts the door, and then after abutment, the lid is removed by the door, whereby the opening of the pod is opened. By this process, the interior of the pod and the interior of the processing apparatus are bought into communication with each other through the small space to allow wafer transferring operations that will be performed repeatedly. All of the support table, the door, the pod side opening portion opening, a mechanism for opening/closing the door and walls partly defining the small space and having the first opening are included in what is referred to as a lid opening and closing system or an FIMS (Front-opening Interface Mechanical Standard) system in the context of the present invention.

As described above, in the past, it is sufficient for the system to handle only a single pod that stores more than ten wafers. However, in the case where the above mentioned thin type pod is used, it is demanded, in order to reduce the process time, that a plurality of pods can be operated simultaneously or the time period over which a pod is on the table can overlap the time period over which another pod is on the table when wafers are supplied into the small space. This operation of wafer transfer can also be applied to transfer of other objects such as reticles that are used in exposure process. In the case where a plurality of low profile pods are to be handled, the plurality of pods may be arranged one above another along a vertical direction to make the area occupied by the system small. A lid opening and closing system in which pods are arranged in this way has been developed and disclosed in Japanese Patent Application Laid-Open No. 2000-286319. In that system, a plurality of pod side opening portions arranged along the vertical directions are provided, and each door that closes each opening portion is adapted to be swung about a shaft extending in the longitudinal direction of the opening portion having a rectangular shape, whereby the space occupied by the mechanism for opening and closing the doors is made small.

### SUMMARY OF THE INVENTION

In the case where a rotary shaft is present in a small space in which downward air flow is ceaselessly produced as is the case with the system disclosed in Japanese Patent Application Laid-Open No. 2000-286319, there is a risk that dust generated at the rotary shaft may brought by the downward air flow onto the surface of a wafer that is being transferred below the rotary shaft. In addition, the lid of the pod is transferred in an environment in which dust control is looser than in the aforementioned small space, and it is considered that dust is present on the lid. There also is a risk that such dust on the lid may be brought downwardly by the downward air flow to attach to the wafer. Furthermore, if there is a time period in the wafer processing process in which a plurality of pods are open simultaneously, the aforementioned dust can enter another pod disposed below. With miniaturization of semiconductor devices and enhancement of performance thereof, it is considered that small dust or like particles that have been of no harm in the past will matter in the future. In view of this, it will be necessary to pay attention to the presence of dust that is produced by the above described mechanism, though it has not been perceived as a significant problem in the past.

The present invention has been made in view of the above described situation. The present invention relates to a lid opening and closing system that handles a plurality of low profile pods that are disposed along the vertical direction. An object of the present invention is to provide a pod lid opening and closing system in which entrance of dust that is generated from a pod upon opening or closing of the lid of the pod or brought by the lid etc. into the small space is controlled and such dust can be prevented from adversely affecting wafers stored in another pod. It is also an object of the present invention to provide a substrate processing method for performing various processing on a wafer using such a lid opening and closing system.

To achieve the above object, according to the present invention there is provided a lid opening and closing system that detaches a lid of a storage container having a substantially box-like body having an opening on one side thereof that can store an object to be stored in the interior thereof and the lid that can be detached from said body and closes said opening to form a closed space in cooperation with said body, to open said opening thereby enabling to bring said object to be stored into/out of said storage container, comprising a storage container support mechanism that supports said storage container and can move said storage container in a predetermined direction, a small space separated from an exterior space, the small space housing a mechanism that transfers said object to be stored under dust control, a tunnel having an exterior space side opening portion near a position at which said storage container support mechanism is loaded with said storage container and a small space side opening portion that opens to said small space to be in communication with said small space, and a door having a holding mechanism that is in contact with said lid and holds it, disposed in said tunnel, swingable about a rotary shaft that is perpendicular to said predetermined direction and parallel to a plane in which said object to be stored extends, and movable in said predetermined direction relative to said storage container moved by said storage container support mechanism, in a position in which it is perpendicular to the direction in which said tunnel extends and it substantially closes said tunnel, wherein the opening of said storage container can be located inside said tunnel when the door has moved relative to said storage container and detached said lid from said storage container, and said tunnel has a size large enough to contain a housing space that can house said door and said lid so that movement of said pod in said predetermined position is not hindered when the door holding said lid has been swung about said rotary shaft.

In the above described system, it is preferred that said rotary shaft and said housing space be located vertically below a moving region of said storage container, and when said door is swung, said door be swung to a position below the moving region of said storage container. Furthermore, in the above described system, it is preferred that said door be connected with said rotary shaft by an L-shaped arm one end of which is connected with said door and the other end of which is connected with said rotary shaft. Still further, in the above described system, it is preferred that a wall portion that defines said housing space have a slit that brings said exterior space and said housing space in communication with each other, the slit being provided at a position on said wall portion at which a projection of a slit present between said door and said lid on said wall is located when said door that holds said lid is disposed in said housing space. Still further, in the above described system, it is preferred that a gap through which air flow flowing from said small space to said exterior space that can remove dust in the vicinity of said storage container be formed between said door and the inner wall of said tunnel when said door is at a position at which it substantially closes said tunnel.

To achieve the aforementioned object, according to the present invention, there is provided a method of processing an object to be stored in which a lid of a storage container having a substantially box-like body having an opening on one side thereof that can store an object to be stored in the interior thereof and the lid that can be detached from said body and closes said opening to form a closed space in cooperation with said body is removed to open said opening thereby enabling to bring said object to be stored into/out of said storage container, said object to be stored is brought into/out of said storage container, and a predetermined processing is performed on said object to be stored in the exterior of said storage container, comprising the steps of preparing a lid opening and closing system including a dust-controlled small space, a stored object transfer mechanism provided in said small space, a door that can substantially close an opening of said small space and hold said lid and a support mechanism that supports said storage container and moves said storage container in a predetermined direction to cause said lid to be held by said door, causing said storage container to be supported by said support mechanism and fixing said storage container on said support mechanism, causing said lid to abut to said door by driving said support mechanism to thereby cause said door to hold said lid, moving said support mechanism and said door in said predetermined direction relative to each other to thereby separate said storage container and said lid, swinging said lid and door about an axis that is perpendicular to said predetermined direction and contained in a plane in which said object to be stored extends to thereby bring said lid and door out of a moving region of said storage container, and moving said storage container in said predetermined direction to set it at a position at which said object to be stored is to be brought into/out of said storage container, wherein said storage container at the time when said lid is separated from said storage container, said lid and door after said swinging and said storage container at the position at which said object to be stored is of be brought into/out of it are located in the interior of a tunnel that connects said small space and a space in which operation of causing said storage container to be supported on said support mechanism is performed.

According to the present invention, after the lid of the pod has been detached from the pod body, the lid and the mechanism for opening and closing the lid can be disposed at a position at which they stay out from downward air flow, or specifically, at a position in the tunnel at which any part of them does not extend into the small space, and the operation of bringing or transferring wafers or the like from/into the pod can per performed in this state. Consequently, dust will not be blown off from the lid of the pod or the mechanism for opening and closing the lid by the downward air flow. Other pods, lids and drive mechanisms for them are also disposed in the respective tunnels. Therefore, the possibility that dust coming from one lid attaches to another lid or other parts again can be reduced.

In addition to the above described features, by disposing the lid opening and closing mechanism, or the rotary shaft specifically, at a position below the pod opening, the possibility that dust or the like generated from that mechanism enters the interior of the pod can be reduced. Furthermore, by disposing the pod opening and closing mechanism and the lid at a position at which they are covered by the pod body upon the operation of bringing a wafer into/out of the pod, dust or the like generated from the pod opening and closing mechanism and dust or the like adhering on the lid during transportation can be prevented from being brought to the pod opening and attaching to a wafer that is brought into/out of the pod. In addition, by causing dust controlled air in the small space that is kept at a pressure higher than the atmospheric pressure to flow through a gap between the circumference of the pod and the inner wall of the tunnel, the possibility that the aforementioned dust or the like enters the interior of the pod can be further reduced.

By providing a slit on the tunnel end wall that defines the housing space for the lid and door in the tunnel at a position aligned with the gap between the lid and the door, dust or the like collected in the gap can be removed there from and discharged to the exterior space simultaneously with the operation of bringing a wafer into/from the pod. Furthermore, by providing a gap or a slit at an appropriate position around the door so that air in the small space can be flow out to the exterior space when the opening is closed, the amount of dust or the like on an end portion of the pod to be inserted into the tunnel can be decreased in advance by the air flow. By adopting the above features in combination, it is possible to address not only the problem of removal of dust or the like between pods, which is the principal problem to be solved by the present invention, but also the problem of entrance of dust or the like generated from the lid etc. into a single pod when the pod is open. The latter problem can matter in a single pod.

One may think that the periphery of the pod opening may be brought into close contact with the wall that defines the small space via a sealing member to prevent dust from entering the small space from the exterior space as is the case, for example, with the system shown in Japanese Patent Application Laid-Open No. 2000-286319. However, in the case where a tunnel is provided between the small space and the exterior space as is the case with the system according to the present invention, if the tunnel has only one opening and air flow cannot be created in the tunnel, there is the possibility that dust is collected in the interior of the tunnel. In view of this, it is advantageous to provide the above mentioned gap or slit etc. to create ceaseless air flow from the interior of the tunnel to the exterior space thereby preventing dust or the like from being collected.

### BRIEF DESCRIPTION OF THE DRAWINGS

FIG. 1A is a side view schematically shows the general structure of the relevant portion of a lid opening and closing system according to an embodiment of the present invention and a pod set on that system.

FIG. 1B is a schematic cross sectional view taken along line 1B-1B in FIG. 1A.

FIG. 1C schematically shows the structure shown in FIG. 1A as seen from the direction indicated by arrow 1C in FIG. 1A.

FIG. 1D schematically shows the structure shown in FIG. 1A as seen from the direction indicated by arrow 1D in FIG. 1A.

FIG. 2 illustrates the structure shown in FIG. 1A in the state in which the pod 2 has been moved and a lid 4 is in abutment with a door 15, in the same manner as FIG. 1A.

FIG. 3A illustrates the structure shown in FIG. 1A in the state in which the pod 2 has been once moved backward and the lid has been detached from the pod body 2a, in the same manner as FIG. 1A.

FIG. 3B is a schematic cross sectional view taken along line 3B-3B in FIG. 3A.

FIG. 4A illustrates the structure shown in FIG. 1A in the state in which the door 15 has been swung and the lid 4 and the door 15 has been received in the housing space 20c, in the same manner as FIG. 1A.

FIG. 4B is a schematic cross sectional view taken along line 4B-4B in FIG. 4A.

FIG. 5A illustrates the structure shown in FIG. 1A in the state in which the pod 2 has been moved to a wafer transfer position at which operation of bringing a wafer 1 into/out of the pod 2 can be performed, in the same manner as FIG. 1A.

FIG. 5B is a schematic cross sectional view taken along line 5B-5B in FIG. 4A.

FIG. 5C schematically shows the structure shown in FIG. 5A as seen from the direction indicated by arrow 5C in FIG. 5A, where illustrations of the lid and the pod body are omitted.

FIG. 6 shows the definition of various dimensions in the embodiment of the present invention.

FIGS. 7A, 7B, 7C, 7D and 7E illustrate the operation of a system according to a modification of the embodiment of the present invention from when the pod is actually set until the pod is moved to the wafer transfer position, in the same manner as FIGS. 1A, 2, 3A, 4A and 5A.

FIG. 8 schematically illustrates another modification of the embodiment of the present invention, in the same manner as FIG. 1A.

FIG. 9 schematically illustrates the general structure of a substrate processing apparatus according to an embodiment of the present invention.

FIG. 10 is an enraged view of a relevant portion of the apparatus shown in FIG. 9.

FIG. 11 illustrates a modification in the same manner as FIG. 10.

### DETAILED DESCRIPTION OF THE PREFERRED EMBODIMENTS

In the following, embodiments of the present invention will be described with reference to the accompanying drawings.

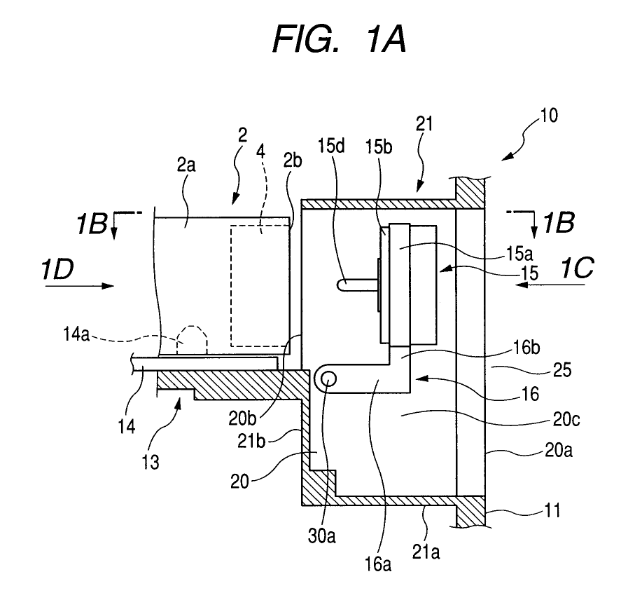

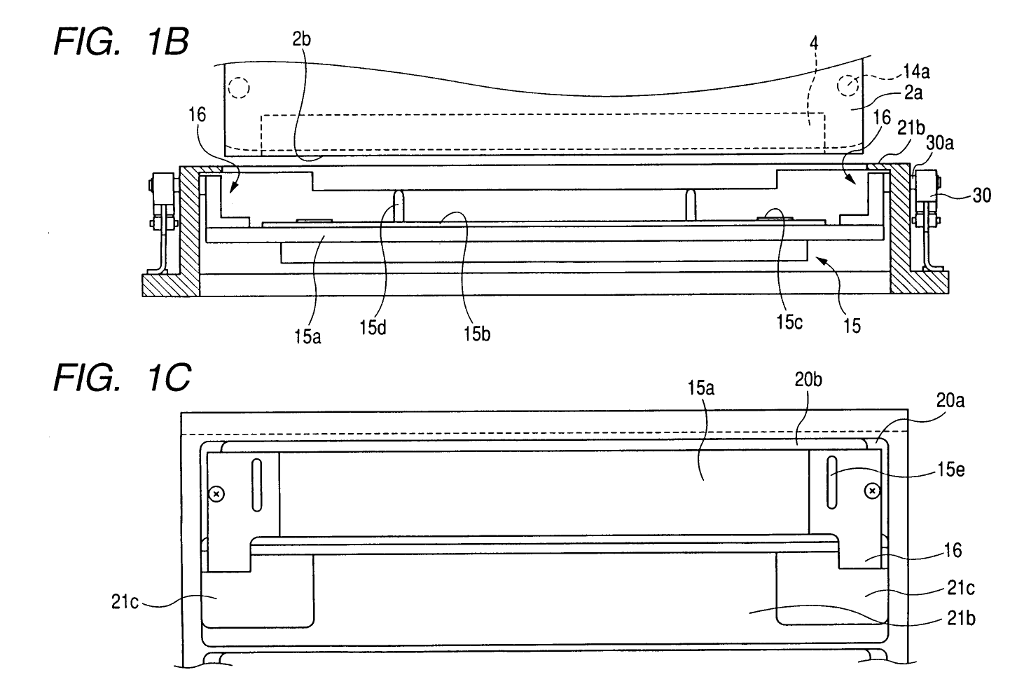

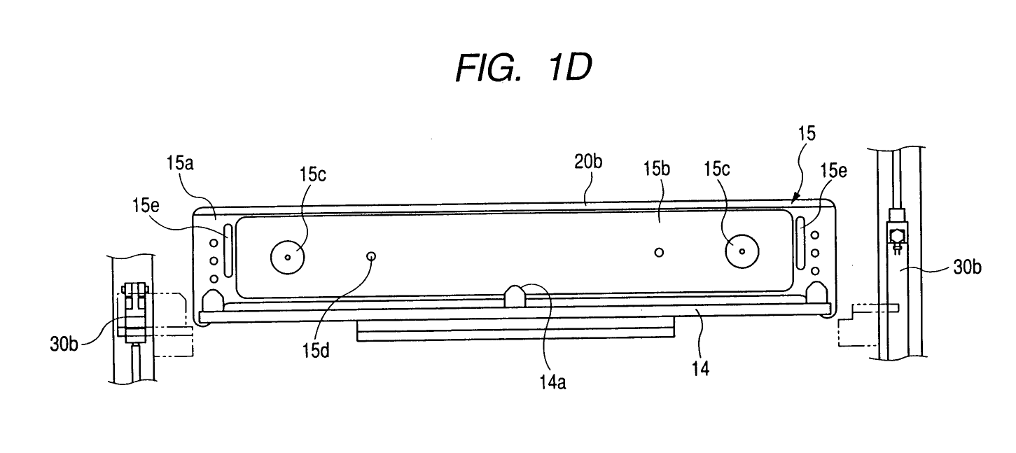

FIG. 1A schematically illustrates a part of a low profile pod and a relevant portion of a lid opening and a closing system that can handle the pod as seen from the side. FIG. 1A shows only one of a plurality of structures or systems that are, in practice, arranged one above another along the vertical direction. To facilitate explanation, the following description of the embodiment will be directed to one system. FIG. 1B is a cross sectional view taken along line 1B-1B in FIG. 1A showing the structure shown in FIG. 1A. FIG. 1C illustrates the structure shown in FIG. 1A as seen from the direction indicated by arrow 1C in FIG. 1A (i.e. from the small space). FIG. 1D illustrates the structure shown in FIG. 1A except for the pod as seen from the direction indicated by arrow 1D in FIG. 1A (i.e. from the exterior space.

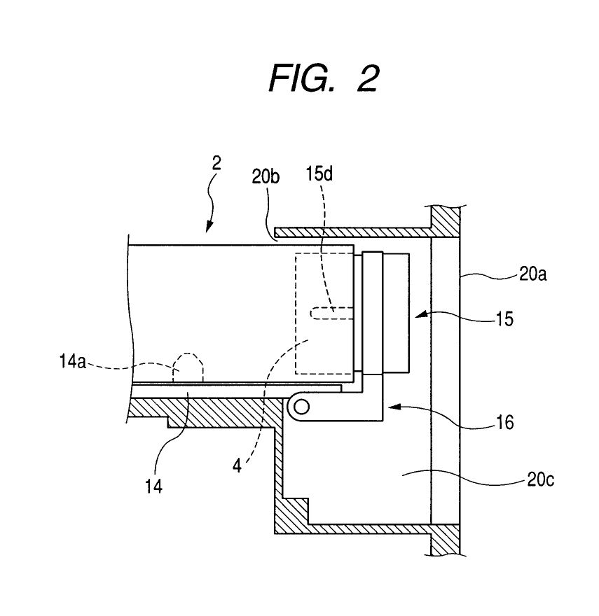

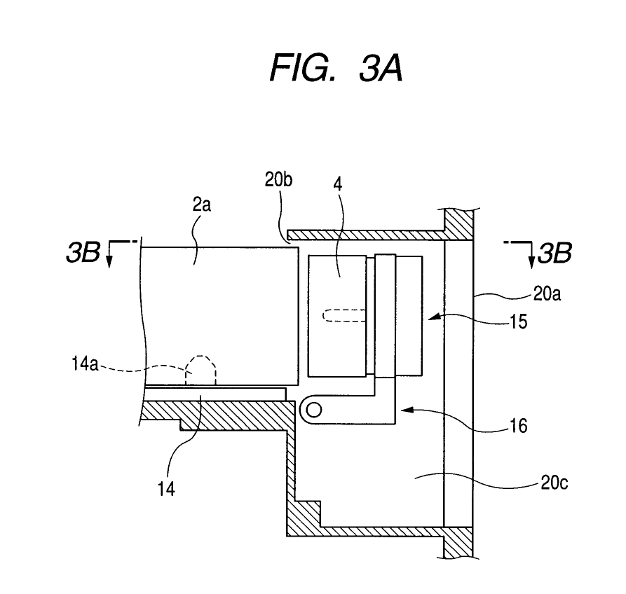

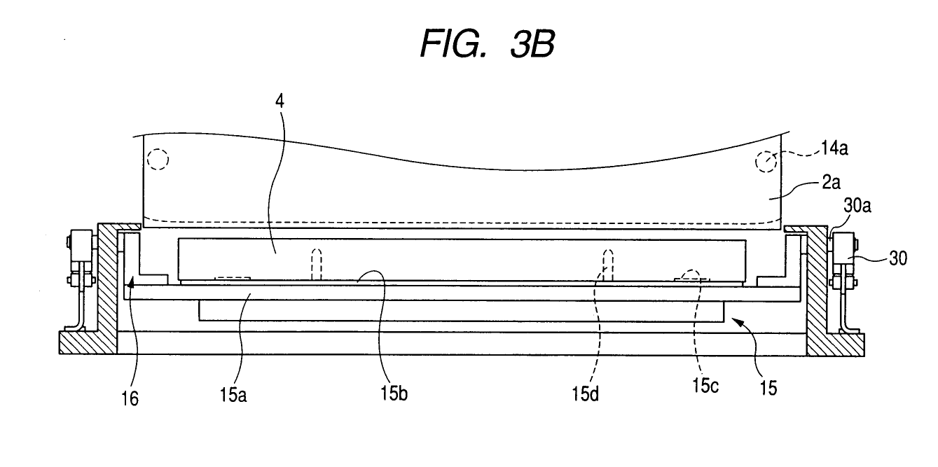

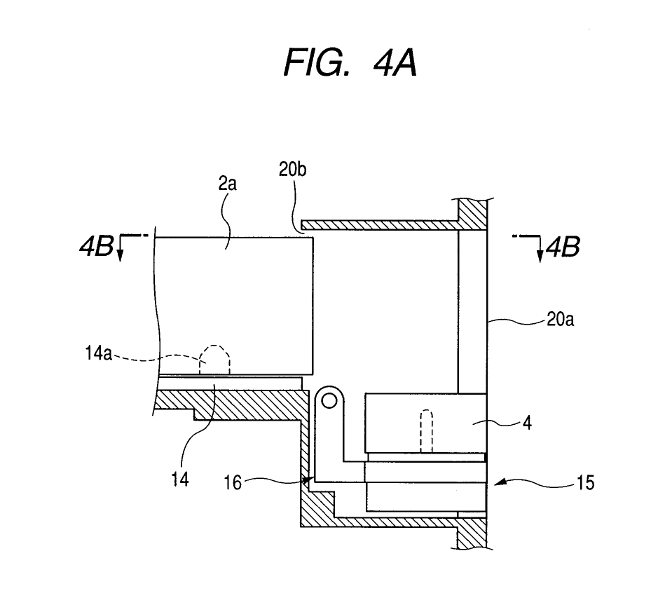

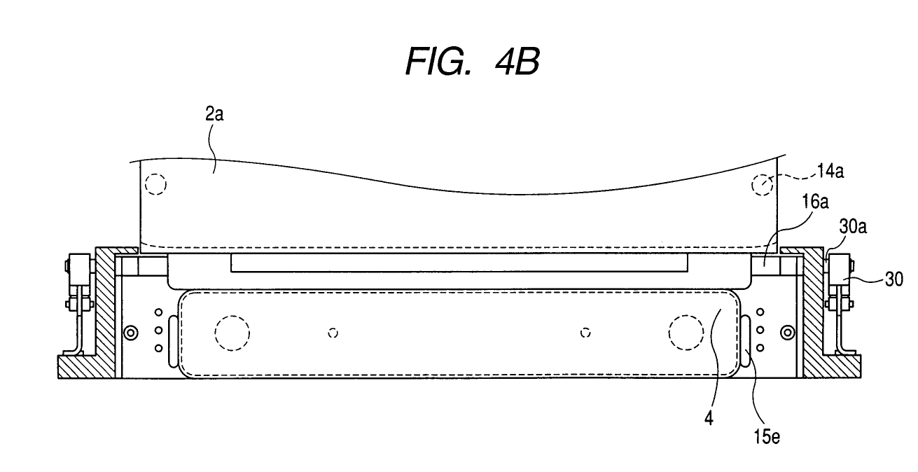

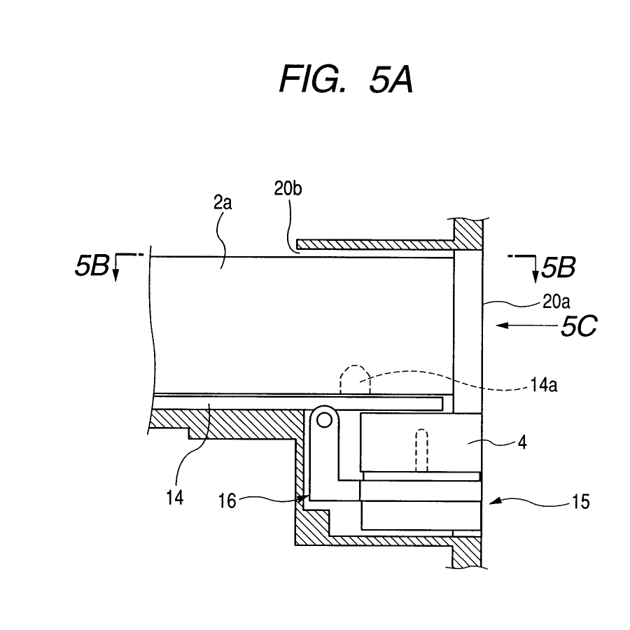

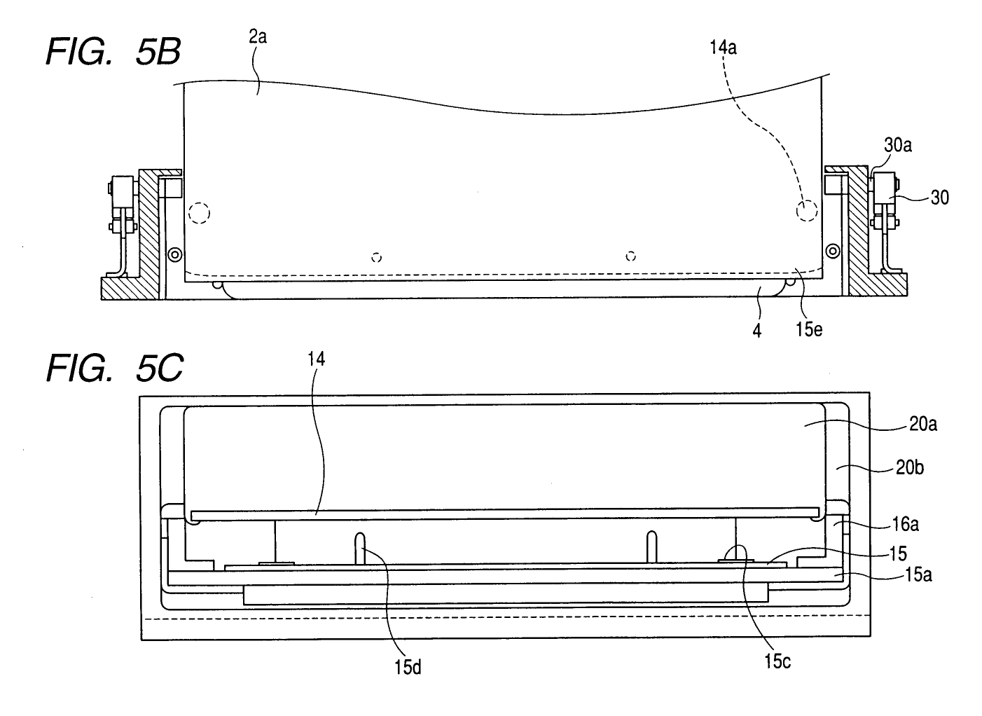

FIG. 1A illustrates a state in which the pod is set on a predetermined position on the support table that will be described later. FIG. 2 illustrates a state in which the lid of the pod is held by a door after the pod has been once driven to advance. FIG. 3A illustrates a state in which the lid has been removed from the pod after the pod has been once driven to retract. FIG. 4A illustrates a state in which the lid opening and closing mechanism and the lid have been moved by an operation of the lid opening and closing mechanism to a housing space for them in the interior of a tunnel. FIG. 5A illustrates a state in which the pod is at a predetermined position that allows wafer transfer from/into it after the pod has been driven to advance further. FIGS. 3B, 4B, 5B illustrate the states shown in FIGS. 3A, 4A and 5A respectively, in the same manner as FIG. 1B. FIG. 5C illustrates the state shown in FIG. 5A in the same manner as FIG. 1C. Note that the pod and the lid are not illustrated in FIG. 5C to facilitate understanding.

First, a description will be made of a pod to be set on this lid opening and closing mechanism and wafers stored in the pod. In the interior of the body 2a of the pod 2 is a space in which one or a few wafers or objects to be processed are to be housed or stored. The pod body 2a is of a low profile box-like shape and has an opening 2b on one of the lateral sides thereof. The pod 2 also has a lid 4 that closes the opening 2b of the body 2a. In the interior of the body 2a is provided a rack (not shown) having a plurality of shelves on which wafers 1 are held horizontally one above another along the vertically direction. The wafers 1 placed on the shelves are disposed at regular intervals in the interior of the pod 2. The wafer 1 constitutes an example of the object to be stored according to the present invention. The pod 2 constitutes an example of the storage container according to the present invention. The body 2a, which has a basically box-like shape, constitutes an example of the body that is defined to have a substantially box-like shape according to the present invention. The opening 2b of the pod 2, which has a basically rectangular shape, constitutes an example of the opening having a substantially rectangular shape according to the present invention.

The lid opening and closing system 10 according to the present invention includes a support table 13, a door 15, a tunnel member 21 that defines a tunnel 20, a door opening and closing mechanism 30 and a wall 11 that constitutes a member that defines a small space 25 (or a transfer chamber that will be described later) with which the tunnel is in communication. The support table 13 has a movable plate 14 having a flat surface on the top thereof on which the pod 2 is actually to be placed. The movable plate 14 can move the pod placed thereon toward and away from an aforementioned opening 20a. The opening 20a is formed on the wall 11 and communicates the small space 25 with the exterior space. Positioning pins 14a are provided on the flat surface of the movable plate 14. The positioning pins 14a are adapted to be fitted into positioning recesses (not shown) provided on the bottom surface of the pod body 2a to uniquely determine the positional relationship between the pod 2 and the movable plate 14. The movable plate 14a is connected with a known drive mechanism (not shown) including a stepping motor, a ball screw and other parts, and the movable plate 14a on which the pod 2 is set can be stopped at four positions that will be described later. The four positions include the pod 2 load position, the lid holding position, the lid removing position and the wafer transfer position. The structure including the support table 13 or the movable plate 14 functions as the storage container support mechanism or the support mechanism that supports the pod and moves it in a predetermined direction according to the present invention.

The tunnel member 21 includes a peripheral wall portion 21a that extends from the wall 11 perpendicularly thereto or in the direction parallel to the moving direction of the movable plate 14 toward the exterior space and has a rectangular cross section that is perpendicular to the direction it extends and an end wall portion 21b that partly confines the opening of the peripheral wall 21a that faces the exterior space. The width of the tunnel 20 defined by the tunnel member 21 (i.e. the horizontal dimension or the dimension of the tunnel 20 in the direction parallel to the longitudinal side of the surface of the pod that is just opposed to the tunnel 20) is designed to be larger than the dimension of the longitudinal side of surface of the pod 2 that is just opposed to the tunnel 20 so that the pod 2 can be received in the tunnel 20. The tunnel 20 opens at the small space side opening 20a and the exterior space side opening 20b. Thus, the tunnel 20 functions as a tunnel that opens in the vicinity of the space in which the pod 2 is placed (or loaded) on the movable plate 14 to bring the exterior space and the small space into communication with each other.

The exterior space side opening 20b has the above mentioned width or horizontal dimension of the tunnel 20 and a height or vertical dimension that is designed to be slightly larger than the dimension of the shorter side of the surface of the pod 2 opposed thereto. Thus, the pod 2 can enter the exterior space side opening 20b. The small space side opening 20a has a width or horizontal dimension that is determined taking into account the above mentioned horizontal dimension of the tunnel 20 that allows the pod 2 to pass and the size of an L-shaped arm 16 so that the L-shaped arm can be disposed aside the pod 2. The height or vertical dimension of the small space side opening 20a is equal to the sum of a dimension that is large enough to leave a housing space 20c in which the door 15 holding the lid 4 of the pod 2 and a part of the door opening and closing mechanism provided in the tunnel 20 are housed and a length slightly larger than the above mentioned vertical dimension of the opposed surface of the pod 2.

The length of the tunnel 20 (that is, the distance from the exterior space side opening 20b to the small space side opening 20a) is designed based on the relationship between the length of two straight portions of the L-shaped arm 16 (which will be described later) that supports the door 15 and the dimension of the shorter side of the lid 4 of the pod 2 or the dimension of the shorter side of the door 15. Specifically, the length of the tunnel 20 is designed in such a way that the portion of the door 15 or the lid 4 that is closest to the small space in the state in which door 15 is at a retracted position (i.e. the position that allows transfer of wafers) does not extends into the small space and the opening of the pod 2 at the position at which the lid 4 is removed from the pod 2 (i.e. the lid removing position) is present in the interior of the tunnel 20. The end wall portion 21b is to confine the exterior space side opening 20b to the above described size. The horizontal dimension of the end wall portion 21b is determined according to the relationship between the size of the opposed surface of the pod 2 and the size of the small space side opening portion 20a. The end wall portion 21b also partly defines the above mentioned space 20c.

The door 15 includes a contact member 15b having a opposed surface that can be opposed to the lid 4 of the pod 2 and has a shape substantially similar to the lid 4 and a door body 15a that holds the contact member 15b by a flat surface to strengthen the contact member 15b. The longitudinal dimension of the door body 15a is shorter than the longitudinal dimension of the small space side opening portion 20a so that the possibility of collision of the door body 15a with the portion that defines small space side opening portion 20a is prevented from occurring when the door body 15a is swung upon opening or closing the lid 4. The contact member 15b is disposed at the center of the door body 15a with respect to the longitudinal direction thereof. On the surface of the contact member 15b that is opposed to the pod 2 are provided suction pads 15c for holding or retaining the lid 4 by vacuum sucking and positioning pins 15d that determines the positional relationship between the lid 4 and the contact member 15b. The positioning pins 15d may have a function of retaining the lid 4, where they also function as a so-called latch keys. At positions on the door body 15a on both sides of the contact member 15b, there are provided slits 15e that pass through the door body 15a from the small space side (or the rear side) to the exterior space side (or the front side) and extends parallel to the shorter side of the door body 15c. One ends (or the fixed ends that will be described later) of the L-shaped arms 16 are attached to portions on the door body 15a on both sides of the contact member 15b. The suction pads 15c and an exhaust system (not shown) that is connected thereto to generate suction force operate as a holding mechanism for holding the lid 4.

The L-shaped arm 16 includes a rotation side straight portion 16a that is connected at its end with the door opening closing mechanism 30 by a rotary shaft 30a that will be described later and a door side straight portion 16b that is connected at its end with the door body 15a. The end of the door side straight portion 16b is the fixed end portion that is fixed to the door body 15a. The door side straight portion 16b extends parallel to the plane of the door body 15a. The rotary shaft 30a is passing through the tunnel member 21 and is connected with the body of the rotational drive mechanism 30b of the door opening and closing mechanism 30. The body of the drive mechanism 30b is disposed outside the tunnel member 21. The body of the drive mechanism 30b includes a known air cylinder and a link mechanism etc. and rotationally drives the rotary shaft 30a between predetermined two angular positions. The rotary shaft 30a is oriented perpendicular to the predetermined drive direction of the movable plate 14 and parallel to a plane perpendicular to the pod opening (i.e. the plane of a wafer stored in the pod).

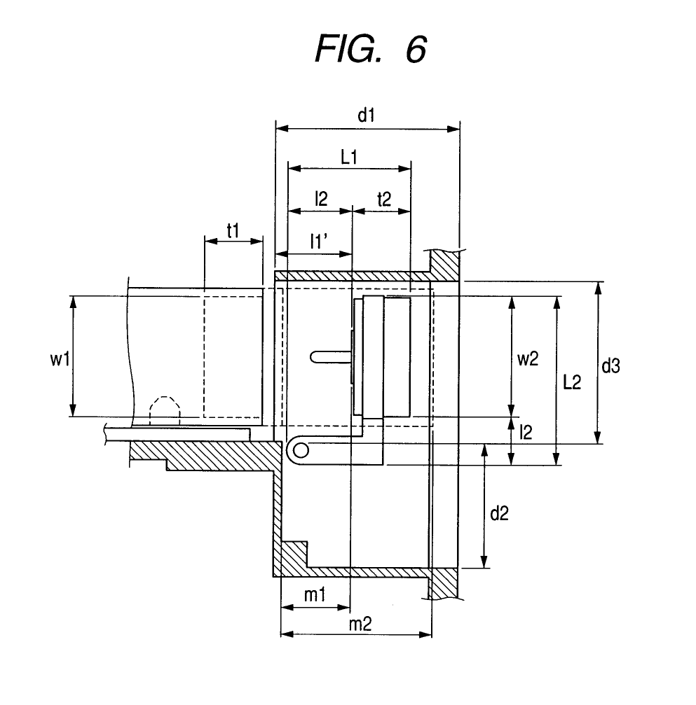

In the following, the relationship between various dimensions of the space in the tunnel 20 and various dimensions of the L-shaped arm 16 with reference to FIG. 6. In FIG. 6, t1 represents the thickness of the lid 4, w1 represents the dimension of the shorter side of the lid 4, l1 represents the distance from the end face of the fixed end portion of the rotary shaft side straight portion 16a of the L-shaped arm 16 to the plane of the suction surface of the suction pads 15c, l1′ represents the distance from the plane at with the exterior space side opening 20b opens to the plane of the above mentioned suction surface, t2 represents the thickness of the door 15 (including the suction pads, contact member and the door body), L1 represents the sum of the l1 and l2, d1 represents the length of the tunnel 20, 12 represents the length of the door side straight portion 16b (i.e. distance from the side of the door 15 to the end face of the portion of the door side straight portion 16b connected to the rotary shaft side straight portion 16a that is opposite to the fixed end portion), w2 represents the length of the shorter side of the door 15 (that is, the shorter side length of the contact member or the door body, whichever is the longer in the shorter side dimension), L2 represents the sum of l1 and w2, d2 represents the distance from the inner surface of the lower wall extending in the longitudinal direction and constituting the peripheral wall 21a of the portion of the tunnel 20 into which the door 15 is to be swung and received to the bottom end of the exterior space side opening portion 20b limited by the end wall portion 21b, and d3 represents the dimension of the shorter side of the exterior space side opening 20b. In addition, m1 represents the distance over which the pod 2 is moved backward from the position at which the surface of the lid 4 opposed to the door abuts the suction pads 15c after the pod 2 has been moved forward to the position at which the pod is stopped after the lid 4 has been removed from the pod 2, and m2 represents the distance over which the pod 2 is moved from the position at which the pod is stopped after the lid 4 has been removed from the pod 2 to the wafer transfer position.

The distance m1 from the position at which the lid 4 of the pod 2 is held to the position at which the lid 4 has been removed is designed to be shorter than the distance l1′ from the surface of the suction pads 15c to the exterior space side opening portion 20b of the tunnel, and the thickness t1 of the lid 4 is designed to be shorter than the distance m1. With this feature, the opening and closing operations of the lid 4 are performed always in the interior of the tunnel 20, and entrance of dust or the like into the interior of the pod can be prevented during the opening and closing operations. By creating air flow from the interior of the tunnel 20 to the exterior space, the amount of dust or the like that enters from the exterior space into the pod through the tunnel can be greatly reduced before and after the opening and closing operations. The travel distance m2 to the wafer transfer position is designed to be shorter than the length of the tunnel 20. Accordingly, the pod opening is always in the interior of the tunnel 20 when the wafer transfer is performed. This can prevent the pod opening from being directly exposed to downward air flow in the small space.

The length w2 of the shorter side of the door 15 is designed to be shorter than the dimension d3 of the shorter side of the exterior space side opening portion 20b of the tunnel 20. By arranging the door at substantially the center of the exterior space side opening portion 20b with respect to the vertical direction, air flow paths that extend straightly from the small space side opening portion 20a to the exterior space side opening portion 20b are formed above the upper side of the door 15 and below the lower side of the door 15. These flow paths and the slits 15e can create air flow toward the exterior space in the circumference of the door 15. The length w1 of the shorter side of the lid 4 is designed to be equal to or shorter than the length of the shorter side of the door 15 so that the above mentioned air flow paths are ensured even when the door 15 is holding the lid 4.

The 15 that is holding the lid 4 is swung about the rotary shaft 30a, so that they are received in the housing space 20c. The above mentioned various dimensions are designed in such a way as to allow this receiving operation. Specifically, the height L2 of the portion including the L-shaped arm 16 and the door 15 before swinging or the sum of dimension l2 and dimension w2 (that is, when the lid is held by the door, the distance between the upper end face of the door or the lid, whichever the higher, and the lowest surface of the L-shaped arm 16) is designed to be shorter than the dimension obtained by subtracting the thickness of the end wall portion 21b from the length d1 of the tunnel 20. With this design, the door 15 and the lid 4 can be prevented from extending from the interior the tunnel 20 into the small space when they are housed in the housing space in the stationary state.

It is desirable that the sum t1+t2 of the thickness t1 of the lid 4 and the thickness t2 of the door 15 be designed to be smaller than the depth or height d2 of the housing space. It is also desirable that dimension L1 be designed to be smaller than dimension d2. By these designs, the lid 4 and the door 15 do not interfere with the movement of the pod 2 at all when the pod 2 is moved to the position at with the wafer transfer operation is performed. In this embodiment, with a view to make the housing space as small as possible, the L-shaped arms 16 are disposed outside the moving range of the pod 2, and cut portions 21c are provided on the end wall portion 21b to prevent it from interfere with the L-shaped arms 16. By these designs, the housing space can be made small, and a space in which air flow may stagnate can be reduced. Actually, a part of the door 15 or the lid 4 momentarily extends from the interior of the tunnel 20 to the small space 25 as the door 15 is swung, but such the time period over which it extends is very short and it does not disturb the downward air flow significantly. In addition, reduction of the housing space 20c is more effective in preventing disturbance or generation of dust. Therefore, in this embodiment, the positional relationship of the components only in the stationary state has been considered.

In the present invention it is essential to provide a space that allows the pod 2 to move backward after the lid 4 has been held by the door 15 and to provide the housing space 20c for receiving door 15 and the lid 4 held by the door 15. Accordingly, it is preferred that the length of the rotary shaft side straight portion and the length of the door side straight portion of the L-shaped arm be determined based on dimensions such as the thickness of the door 15 and the thickness of the lid 4 with a view to provide these spaces. It is also preferred that the position of the rotary shaft 30a be designed taking into consideration the above. From the above point of view, the rotary shaft side straight portion of the L-shaped arm may be designed, for example, to have an extendable structure, and an extending and retracting mechanism may be further provided to drive it to a desired position at an appropriate time. In this case, the extending and retracting mechanism may include, for example, an air cylinder that can stop at two positions.

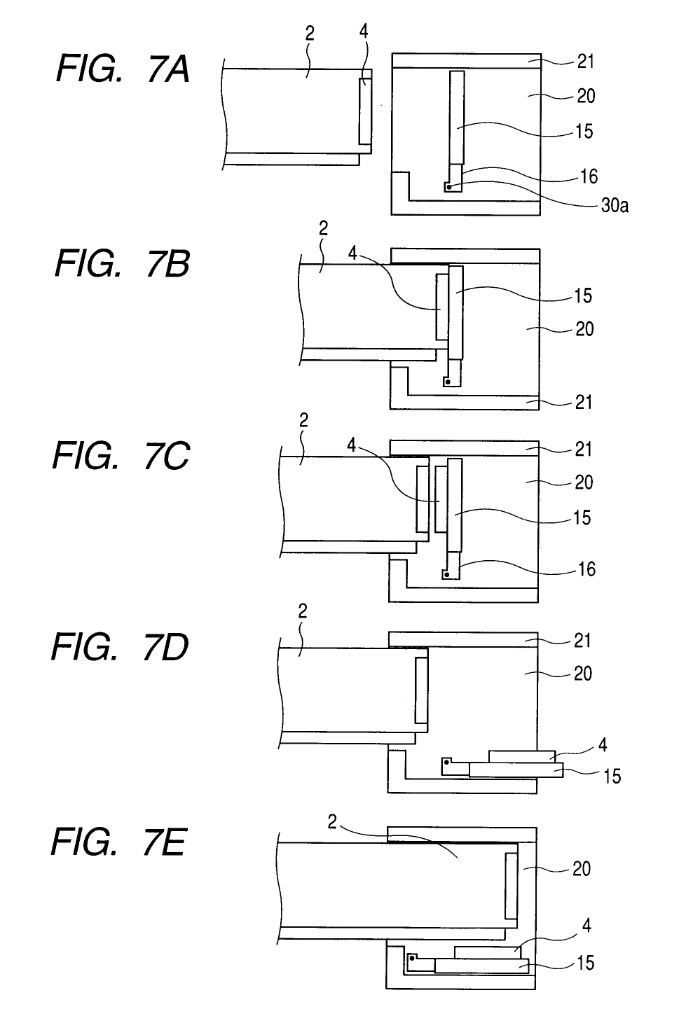

As a modification of this embodiment, the rotary shaft 30a may be adapted to be moved. An example of such a structure is shown in FIGS. 7A to 7E. FIG. 7A corresponds to FIG. 1A, FIG. 7B corresponds to FIG. 2A and FIG. 7C corresponds to FIG. 3A. FIGS. 7D and 7E illustrate the operations of components that are specific to the modification, in the same scheme. Components having functions and effects similar to those shown in FIG. 1A etc. will be denoted by like reference signs and will not be further described in detail. In this modification, after the door 15 and the lid 4 held by it have been swung into the housing space 20a, they are driven to be moved toward the end wall portion 21b with the rotary shaft 30a, whereby the door 15 and other components are prevented from extending from the tunnel 20 into the small space.

With the above described structure, the depth or height d2 of the housing space can be made small, whereby the degree of stagnation of air flow in the housing space can be reduced and dust staying therein with stagnation can be reduced. However, in this modification, it is necessary to design the configuration of the mechanism for actually achieving the above described operation and to take care of dust that can be generated upon operation of such a mechanism. For this reason, the former described embodiment is currently considered to be preferable.

In this embodiment, the door 15 and the rotary shaft 30a are linked by the two L-shaped arms 16. However, the arm may be replaced by an integral member having an L-shaped cross section produced by bonding two boards, and the integral member may be attached to the door. In other words, the door itself may be designed to have an L-shaped cross section. In such a modification, it is preferred that an appropriate slit(s) be provided on the door so that air flow from the small space toward the exterior space is created at an appropriate position. In this modification, it is necessary to make the housing space 20c larger than that in the above described embodiment in order to prevent the board connected to the rotary shaft from interfering with the end wall portion 21b after swinging of the door or with the moving region of the pod 2. Although this modification is disadvantageous accordingly in that the region in which stagnation of air flow occurs is enlarged, it is advantageous in that the isolation of the small space 25 from the exterior space by the door 15 is greatly improved, and the possibility of entrance of dust or the like into the small space 25 from the exterior state in the state in which the pod 2 is not set can be greatly reduced.

In the following, the actual operation of the lid opening and closing mechanism having the above described structure will be described. First, the pod 2 is placed on the movable plate 14 at the loading position in the state in which opening of the tunnel 20 is substantially closed by the door 15, as shown in FIGS. 1A to 1D. After the pod 2 has been set at a predetermined position on the movable plate 14 with the aid of the positioning pins 14a, the movable plate 14 is advanced toward the door 15 by a drive mechanism that is not shown in the drawings. The movement of the movable plate 14 by the drive mechanism is stopped at the position at which the lid 4 that closes the pod 2 comes into abutment with the suction pads 15c. In this process, the positioning pins 15d get into positioning recesses (not shown) provided on the lid 4, whereby inappropriate positioning in the abutment of the lid 4 and the door 15 is prevented from occurring. After the abutment, the exhaust mechanism (not shown) is operated, so that the suction pads 15 holds lid 4 by suction. The system in this state is illustrated in FIG. 2A.

After the lid 4 is held by the door 15 by means of the suction pads 15c, the movable plates 14 on which the pod 2 is set is moved backward to a predetermined lid removal position. With this backward movement, the lid 4 held by the door 15 is detached from the opening portion 2b of the pod 2. Upon detachment, the lid 4 may possibly be sticking to the pod body 2a due to a sealing member (not shown) or a pressure difference between the interior of the pod 2 and the exterior space. In view of this, it is desirable that the pod body 2a be secured to the movable plate 14 by some means. In the case of this embodiment, the positioning pins 14a are designed to be significantly long so that the pins 14a retain the pod body 2a against the force acting on the pod body 2a from the lid 4 at the time when the movable plate is moved backward. FIGS. 3A and 3B illustrate the system in the state in which the movable plate 14 has been retracted to the predetermined position or the lid removal position at which the lid 4 has been detached from the pod body 2a.

While the movable plate 14 is kept stationary at the above described position, the door 15 is swung by the door opening and closing mechanism 30. The swinging of the door 15 is stopped in the state illustrated in FIGS. 4A and 4B in which the door 15 and the lid 4 are housed in the housing space 21. Thereafter, the movable plate 14 is moved forward, and when the pod 2 comes to the position at which wafer transfer or the operation of bringing a wafer out of/into the pod is to be performed, the movable plate is stopped. The system in this state is illustrated in FIGS. 5a and 5B. In this state, the lid 4 and the door 15 are located beneath the pod 2 with the movable plate 14 between. For this reason and thanks to an additional effect of downward air flow generated in the small space 25, dust on the lid 4 etc. cannot enter the interior of the pod 2 easily. In addition, by generating downward air flow, the interior of the small space is kept at a pressure higher than the pressure in the exterior space. Accordingly, air flow from the small space to the exterior space is always present in the interior of the tunnel 20, whereby the possibility that dust on the lid 4 or other parts is brought toward the opening 2b of the pod 2 is further reduced. In the present invention, furthermore, an appropriate gap is designed to be left between the inner surface of the tunnel 20 and the periphery of the door and the periphery of the pod in order to achieve the above effect. The gap is designed in such a way that the pressure difference between the small space and the exterior space is not made unduly low, and air flow flowing through that gap at a flow rate that is not excessively high is generated.

In this embodiment, in order to separate the small space 25 and the exterior space to a significant extent to limit the region that allows communication between these spaces, the system is designed in such a way that air flow that flows from inside the housing space 20c straightly to the exterior space cannot be created. However, there is a small gap between the surface of the lid 4 that faces the door 15 and the contact member 15b in the region other than the region in contact with the suction pads 15c. If there is dust or the like in that gap, it is considered to be difficult for the above described system to efficiently remove it out to the exterior space. In the case where the degree of dust control in the external environment is not so high, the possibility that dust remains on the opposed surface of the lid 4 would be high. In such an environment, it is preferred that a slit be provided on the end wall portion 21 at a position to be aligned with the above mentioned gap so that an air flow path from the small space 25 to the above mentioned gap and then to the slit to facilitate removal of dust in the gap to the exterior space by the air flow flowing through the gap.

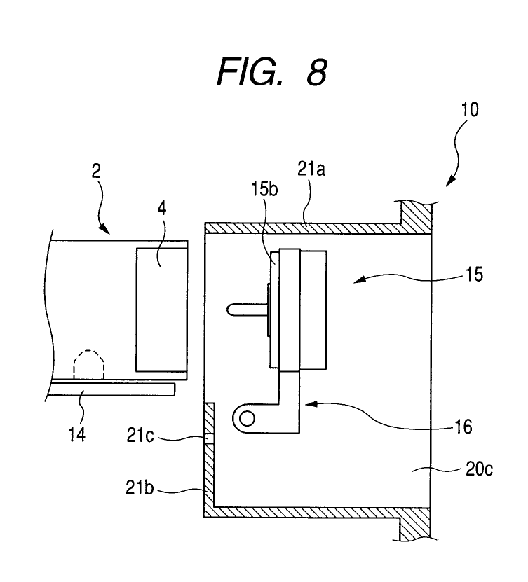

FIG. 8 shows a system in which such a slit is provided. FIG. 8 shows an exemplary system in the same manner as FIG. 1A. As shown in FIG. 8, an end wall slit 21c is provided on the end wall portion 21b at a predetermined position opposed to the gap between the contact member 15b and the lid 4 when the door 15 is at the predetermined stationary position in the housing space 20c after it has been swung. By providing the slit 21c, ceaseless air flow that flows straightly through the gap between the contact member 15b and the lid 4 that are housed in the housing space 20c can be created, whereby dust or the like in the gap can be efficiently brought out to the exterior space. The position and the number of the end wall slit(s) 21 are not limited to those of the illustrated embodiment, but a further slit(s) may be provided according to the shape of the door 15 or the lid 4 or other factors so that an air flow path passing through a region in which dust or the like can likely be present is created to enable to remove dust.

By using the lid opening and closing system having the above described structure, after the lid of the pod has been detached from the pod body, the lid and the mechanism for opening and closing the lid can be disposed at a position at which they stay out from downward air flow, or specifically, at a position in the tunnel at which any part of them does not extend into the small space, and the operation of bringing or transferring wafers or the like out of/into the pod can be performed in this state. Consequently, dust will not be blown off from the lid of the pod or the mechanism for opening and closing the lid by the downward air flow. Other pods, lids and drive mechanisms for them are also disposed in the respective tunnels. Therefore, the possibility that dust coming from one lid attaches to another lid or other parts can be reduced. In the foregoing, the structure in which the door and other components are swung to a position beneath the pod driving region so that they are covered by the pod during the wafer transfer process has been described as the best mode of the present invention. However, the problem of removal or migration of dust between pods can be solved by providing the tunnel, and the effects of the invention would be achieved to some extent even in the case in which the above described embodiment is modified in such a way that the door is swung upwardly. The system according to such a modification may be designed in such a way that the pod opening is positioned on the small space side of the swing stop position upon wafer transferring operations, whereby dust generated from the door is brought out to the exterior space by air flow flowing through the gap formed between the door in the stationary state and the pod, and the dust thus generated can be prevented from entering the interior of the pod to some extent.

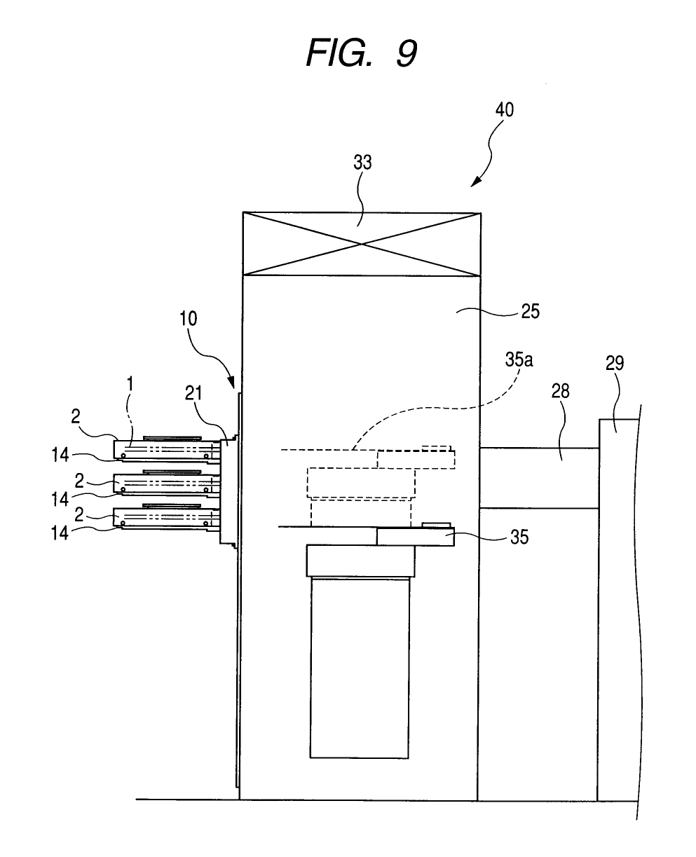

In the following, a substrate processing apparatus in which the lid opening and closing system described in the foregoing is practically used will be described as an exemplary embodiment of the present invention. FIG. 9 is a side view schematically showing the general structure of a semiconductor wafer processing apparatus (or substrate processing apparatus) 40 that can operate in a so-called mini-environment system. The semiconductor wafer processing apparatus 40 mainly includes a load port portion (or FIMS system, lid opening and closing apparatus) 10, a transfer chamber (or small space) 25 and a processing chamber 29. These sections are partitioned by the wall 11 on the load port side and the communication passage 28 on the processing chamber side. In the transfer chamber 25 of the semiconductor wafer processing apparatus 40, downward air flow from the top to the bottom of the transfer camber 25 is created by a fan filter unit 33 provided in the top portion thereof to keep a high degree of cleanliness by bringing out dust. The bottom panel of the transfer chamber 25 comprises a mesh that constitutes outlet paths of the downward air flow. With the above described structure, dust-controlled air is ceaselessly introduced into the transfer chamber 25, and dust present in the chamber or dust brought into the chamber from a pod or other components is always brought downward by the downward air flow and brought out to the exterior.

Pods 2 or storage containers for silicon wafers or the like (which will be simply referred to as wafers hereinafter) are set on support tables 14 of the load port 10. In the apparatus according to this embodiment, three pods are set one above another and two wafers 1 are held in each pod 2. As described before, the interior of the transfer chamber 25 is kept in a highly clean condition for processing wafers 1. In addition, a transfer robot 35 that can actually hold a wafer is provided as a transfer mechanism. The transfer robot 35 can move in the direction along which the pods 2 are arranged (i.e. the vertical direction). The robot arm 35a of the transfer robot 35 can rotate 360 degrees about a shaft. Wafers 1 are transferred between the interior of the pod 2 and the interior of the processing chamber 29 by the transfer robot 35. In the processing chamber 29 are provided various mechanisms that perform various processing such as film deposition and film processing. Descriptions of these mechanisms will be omitted, since they do to have direct relevance to the present invention.

The pod 2 includes a box-like body 2a having an opening on one side thereof and an interior space in which two wafers 1 to be processed are to be stored and a lid 4 that closes the opening. In the interior of the body 2a is provided a rack having a plurality of shelves on which wafers are to be placed one above the other along one direction. The wafers 1 placed thereon are stored in the interior of the pod 2 at a specific interval. In the illustrated system, the tunnel member 21 has a plurality of tunnels (three tunnels) 20 provided therein at positions opposed to the movable plates 14. The details of the structure of each tunnel are the same as those of the structure having been already described above. Accordingly, to make understanding of the drawings easier, further description and detailed illustration thereof will not be made.

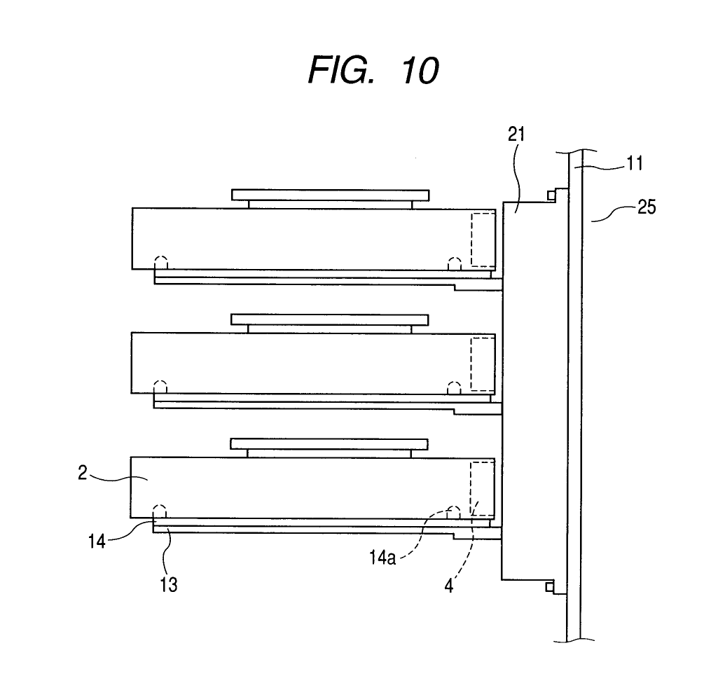

FIG. 10 is an enlarged view of the lid opening and closing system 10 shown in FIG. 9. In conventional FISM systems adapted to a pod in which a lot of wafers are stored, since the lid of the pod necessarily has a somewhat large size, the door that is adapted to detach the lid and closes the opening portion of the small space is necessarily required to be moved in the small space and stopped in that space. In the present invention, since the door has a narrow plate-like shape, the state in which transfer of wafers from the pod can be performed is achieved by enabling relative movement of the pod and the door by an amount equal to the width of the lid and swinging the lid and the door to outside the moving region of the pod. Accordingly, the door opening and closing mechanism can be disposed in the tunnel that is independent from the small space 25 as shown in FIG. 9.

For example, in the case where the robot is driven by a combination of operations of three systems such as X, Y and Z systems, if there are obstacles to be avoided in driving the robot in all the driving directions, a significantly complex safety circuit is needed in order to achieve safe operation of the robot. In the present invention, there is not a structure that extends into the small space 25 that can be obstacle to driving of the robot in the vertical direction (Z-axis direction). Therefore, a safety circuit is needed only when transfer of wafers is performed. Accordingly, the circuit configuration can be made much simple. Furthermore, since no structure is disposed in the small space 25 except for the robot 35, there is no structure that can disturb downward air flow, especially in the region near the pod opening. Therefore, efficiency of dust removal by the downward air flow is enhanced. In addition, the possibility of dust generation from the door or other components caused by a disturbance in the downward air flow is reduced. According to the SEMI (Semiconductor Equipment and Materials International) standards established in the semiconductor industry, it is not allowed to provide a projection on the inner surface of the wall that defines the small space in the vicinity of the opening portion used to transfer wafers. The present invention is compliant with the standards.

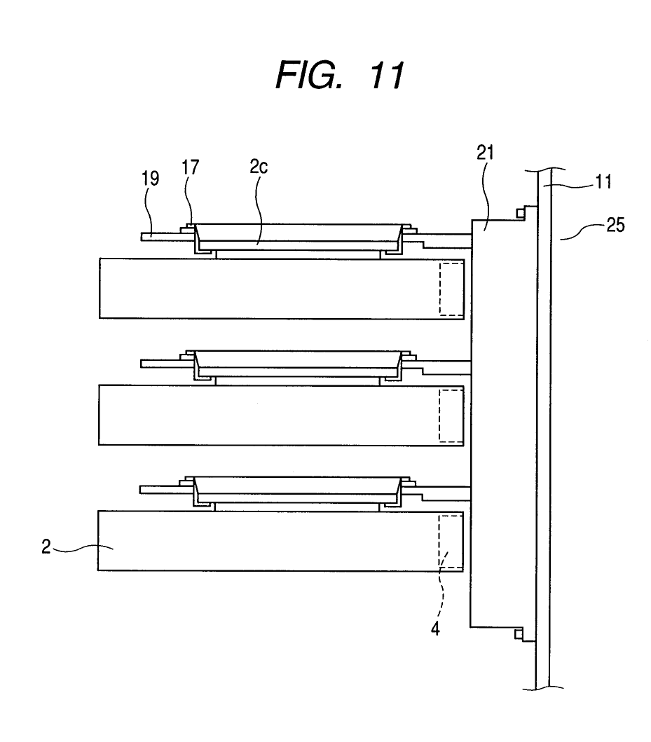

In the above described embodiment, the pod 2 is placed on the movable plate 14 provided on the support table 13. However, the structure to which the present invention is applied is not limited to this embodiment. For example, the pod 2 may be suspended from above. Such a modification is shown in FIG. 11 in the same manner as FIG. 10. In transporting the pod 2 by so-called automatic handling, an upper flange 2c fixedly provided on the top surface of the pod 2 is used. The pod 2 is transported by suspending the flange. In this modification, the pod 2 that has been transported is held by a suspension member 17, and the pod 2 is transferred with the suspension member 17 by a suspension member drive mechanism 19.

In this modification, the movable plate 14 used in the above described embodiment can be eliminated, and the situation in which the plate enters the interior of the tunnel 20 with the pod 2 can be prevented. Therefore, it is possible to eliminate the space for receiving the entering plate that is required to be provided in the housing space 20c in the above described embodiment. However, in the above described embodiment, the pod body 2a can be retained on the movable plate 14 with a strength that can resist the force acting on the pod body 2a upon detachment of the lid 4 to some extent. In this modification, there is a possibility that the simple suspension does not provide a force strong enough to retain the pod body 2a upon detachment of the lid, and it may be necessary to design the structure in such a way as to enable retaining of the pod body or provide an additional component therefor. However, since such a component can be additionally used, the storage container support mechanism or the support mechanism in the present invention should be construed to include the structure like this modification.

According to the present invention, a lid opening and closing system in which a component or structure that extends into the small space is eliminated. In that system, there is no component or structure that extends into the water transferring side, full use can be made of effects of downward air flow created in the small space. In addition, the control program of the transfer robot used in the operation of transferring wafers can be made easy and high speed movement of the robot can be easily achieved, since a component or structure to be avoided by the robot upon movement along the Z-axis in which high speed movement is required has been eliminated. Furthermore, since the pod openings are separated by the tunnels, the possibility that dust entering with a pod or generated from a pod enters another pod can be reduced. Still further, since while wafers are actually transferred, the lid, door and its drive mechanism are disposed beneath the bottom of the pod and covered by the bottom portion of the pod, the possibility that dust generated from them enters the interior of the pod can be reduced.

Although the above described embodiments or examples have been directed to FOUP and FISM systems, the applications of the present invention are not limited to them. The lid opening and closing apparatus according to the present invention can be applied to any front open type container in which a plurality of objects are to be stored and any system that opens the lid of the container and transfers objects stored out of/into the container.

This application claims priority from Japanese Patent Application No. 2007-197321 filed Jul. 30, 2007, which is hereby incorporated by reference herein.

What is claimed is:

1. A lid opening and closing system that detaches a lid of a storage container having a substantially box-like body having an opening on one side thereof that can store an object to be stored in the interior thereof and the lid that can be detached from said body and closes said opening to form a closed space in cooperation with said body, to open said opening thereby enabling to bring said object to be stored into/out of said storage container, comprising:
a storage container support mechanism that supports said storage container and can move said storage container in a predetermined direction;
a small space separated from an exterior space, the small space housing a mechanism that transfers said object to be stored under dust control;
a tunnel having an exterior space side opening portion near a position at which said storage container support mechanism is loaded with said storage container and a small space side opening portion that opens to said small space to be in communication with said small space; and
a door having a holding mechanism that is in contact with said lid and holds it, disposed in said tunnel, swingable about a rotary shaft that is perpendicular to said predetermined direction and parallel to a plane in which said object to be stored extends, and movable in said predetermined direction relative to said storage container moved by said storage container support mechanism, in a position in which it is perpendicular to the direction in which said tunnel extends and it substantially closes said tunnel,
wherein the opening of said storage container can be located inside said tunnel when the door has moved relative to said storage container and detached said lid from said storage container, and said tunnel has a size large enough to contain a housing space that can house said door and said lid so that movement of said pod in said predetermined position is not hindered when the door holding said lid has been swung about said rotary shaft.

2. A lid opening and closing system according to claim 1, wherein said rotary shaft and said housing space is located vertically below a moving region of said storage container, and when said door is swung, said door is swung to a position below the moving region of said storage container.

3. A lid opening and closing system according to claim 1, wherein said door is connected with said rotary shaft by an L-shaped arm one end of which is connected with said door and the other end of which is connected with said rotary shaft.

4. A lid opening and closing system according to claim 1, wherein a wall portion that defines said housing space has a slit that brings said exterior space and said housing space in communication with each other, the slit being provided at a position on said wall portion at which a projection of a slit present between said door and said lid on said wall is located when said door that holds said lid is disposed in said housing space.

5. A lid opening and closing system according to claim 1, wherein a gap through which air flow flowing from said small space to said exterior space that can remove dust in the vicinity of said storage container is formed between said door and the inner wall of said tunnel when said door is at a position at which it substantially closes said tunnel.

6. A method of processing an object to be stored in which a lid of a storage container having a substantially box-like body having an opening on one side thereof that can store an object to be stored in the interior thereof and the lid that can be detached from said body and closes said opening to form a closed space in cooperation with said body is removed to open said opening thereby enabling to bring said object to be stored into/out of said storage container, said object to be stored is brought into/out of said storage container, and a predetermined processing is performed on said object to be stored in the exterior of said storage container, comprising the steps of:
preparing a lid opening and closing system including a dust-controlled small space, a stored object transfer mechanism provided in said small space, a door that can substantially close an opening of said small space and hold said lid, and a support mechanism that supports said storage container and moves said storage container in a predetermined direction to cause said lid to be held by said door;
causing said storage container to be supported by said support mechanism and fixing said storage container on said support mechanism;
causing said lid to abut, to said door by driving said support mechanism to thereby cause said door to hold said lid;
moving said support mechanism and said door in said predetermined direction relative to each other to thereby separate said storage container and said lid;
swinging said lid and door about an axis that is perpendicular to said predetermined direction and contained in a plane in which said object to be stored extends to thereby bring said lid and door out of a moving region of said storage container; and
moving said storage container in said predetermined direction to set it at a position at which said object to be stored is to be brought into/out of said storage container,
wherein said storage container at the time when said lid is separated from said storage container, said lid and door after said swinging and said storage container at the position at which said object to be stored is to be brought into/out of it are located in the interior of a tunnel that connects said small space and a space in which operation of causing said storage container to be supported on said support mechanism is performed.
